(19) United States
(12) Patent Application Publication
(10) Pub. No.: US 2004/0102039 A1
(43) Pub. Date: May 27, 2004

(54) Method for forming landing plug in semiconductor device

(76) Inventors: Kwan-Yong Lim, Ichon-shi (KR); Heung-Jae Cho, Ichon-shi (KR)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/636,854

(22) Filed: Aug. 6, 2003

(30) Foreign Application Priority Data
Nov. 27, 2002 (KR) 2002-74275

(51) Int. Cl. H01L 21/4763; H01L 21/425; H01L 21/44

(52) U.S. Cl. 438/674; 438/675; 438/641

(57) ABSTRACT

The present invention relates to a method for forming a landing plug capable of securing a low resistance by employing a selective epitaxial growth technique to meet demands of high-integration and high-speed in a semiconductor device. The method includes the steps of: forming an inter-layer insulation layer on a substrate; forming a contact hole by etching the inter-layer insulation layer until exposing a partial portion of the substrate; forming a first conductive layer with a predetermined thickness inside of the contact hole, the first conductive layer being made of a silicon layer; forming a second conductive layer on the inter-layer insulation layer in such a manner of being buried into the contact hole in which the silicon layer is formed; and performing a blanket etch process to the second conductive layer until exposing surfaces of the inter-layer insulation layer and the hard mask so that a landing plug is formed.

### FIELD OF THE INVENTION

The present invention relates to a method for forming a plug in a semiconductor device; and, more particularly, to a method for forming a landing plug in a semiconductor device through the use of a selective epitaxial growth (SEG) technique.

### DESCRIPTION OF RELATED ARTS

As a semiconductor device gets highly integrated, it is required to develop a metal-oxide semiconductor field effect transistor (MOSFET) of which gate length is below about 0.1 μm. Also, a height of a capacitor increases to above about 1 μm to secure a sufficient capacitance within a limited narrow area. This increased capacitor height further results in an increase of a depth of a contact hole formed for a contact between a storage node contact of the capacitor and a wiring. For this reason, a landing plug typically having a structure of ploy plug pad (PPP) is used to form such contact.

Referring to FIGS. 1A to 1D, there is described a convention method for forming a landing plug to which the PPP structure is applied.

Referring to FIG. 1A, a gate insulation layer 12 is formed on a semiconductor device providing a device isolation layer 11 with a shallow trench isolation structure, and a polysilicon layer 13 and a metal layer 14 are sequentially formed thereon. Then, a hard mask 15 is formed on the metal layer 14. With use of the hard mask 15, the metal layer 14 and the polysilicon layer 13 are etched so to form a gate 100. An insulation layer is deposited on an entire surface of the substrate 10 and proceeded with a blanket etch process so that a spacer 16 is formed at lateral sides of the hard mask 15 and the gate 100.

Referring to FIG. 1B, an inter-layer insulation layer 17 is deposited on the above entire surface of the substrate 10 so as to fill a space between the spacers 16. The substrate 10 is then etched to expose a surface of the hard mask 15 and is planarized by performing a chemical mechanical polishing (CMP) process thereto. Afterwards, the inter-layer insulation layer 17 is etched to expose a partial portion of the substrate 10 disposed between the spacers 16, whereby a contact hole 18 is formed.

Referring to FIG. 1C, a polysilicon layer 19 is deposited on the inter-layer insulation layer 17 to be buried in the contact hole 18. As shown in FIG. 1D, the polysilicon layer 19 is entirely etched to expose surfaces of the hard mask 15 and the inter-layer insulation layer 17 through a CMP process. As a result, a landing plug 19A with the PPP structure is formed.

However, it is difficult to obtain a low resistance with use of the landing plug having the PPP structure owing to a fact that a contact area gets largely decreased as a semiconductor device is highly integrated. Therefore, instead of using the PPP structure, a selective epitaxial growth (SEG) technique is currently applied for selectively growing silicon within the contact to form a landing plug. This recent application of the SEG technique allows the landing plug to have a low resistance and simplifies subsequently performed processes since it is possible to eliminate such process as the CMP. Also, since silicon is selectively grown on the contact portion, this SEG technique does not have a gap-fill problem even if the contact hole is deep.

However, the SEG technique has a limitation to decrease the resistance up to a certain point. For instance, in case of a next generation semiconductor device of which gate length is below about 0.1 μm, it is difficult to secure a sufficiently low resistance suitable for such semiconductor device. A device operation speed is reduced due to a resistance-capacitance delay, thereby being unable to meet the demands of high-integration and high-speed in a semiconductor device.

### SUMMARY OF THE INVENTION

It is, therefore, an object of the present invention to provide a method for forming a landing plug in a semiconductor device capable of securing a sufficiently low resistance corresponding to demands of high-integration and high-speed by applying a selective epitaxial growth (SEG) technique.

In accordance with an aspect of the present invention, there is provided a method for forming a landing plug, including the steps of: forming an inter-layer insulation layer on a substrate; forming a contact hole by etching the inter-layer insulation layer until exposing a partial portion of the substrate; forming a first conductive layer with a predetermined thickness inside of the contact hole, the first conductive layer being made of a silicon layer; forming a second conductive layer on the inter-layer insulation layer in such a manner of being buried into the contact hole in which the silicon layer is formed; and performing a blanket etch process to the second conductive layer until exposing surfaces of the inter-layer insulation layer and the hard mask so that a landing plug is formed.

### BRIEF DESCRIPTION OF THE DRAWINGS(S)

The above and other objects and features of the present invention will become apparent from the following description of the preferred embodiments given in conjunction with the accompanying drawings, in which:

FIGS. 1A to 1D are cross-sectional views illustrating a conventional method for forming a landing plug in a semiconductor device;

FIGS. 2A to 2E are cross-sectional views illustrating a method for forming a landing plug in a semiconductor device in accordance with a first preferred embodiment of the present invention; and

FIGS. 3A to 3E are cross-sectional views illustrating a method for forming a landing plug in semiconductor device in accordance with a second preferred embodiment of the present invention.

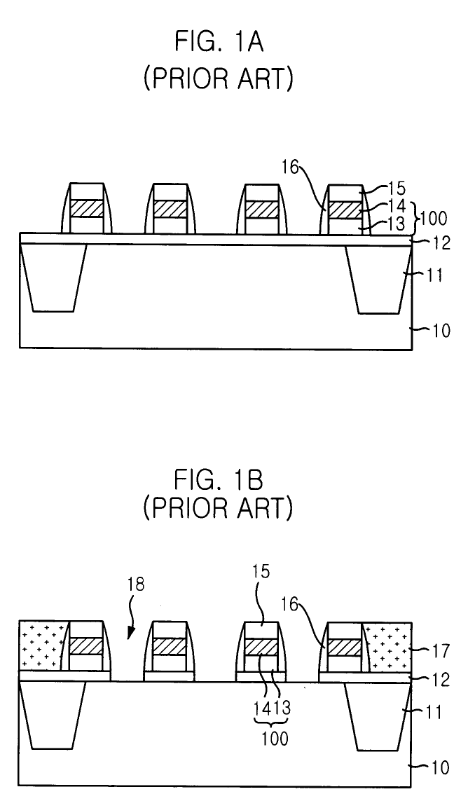

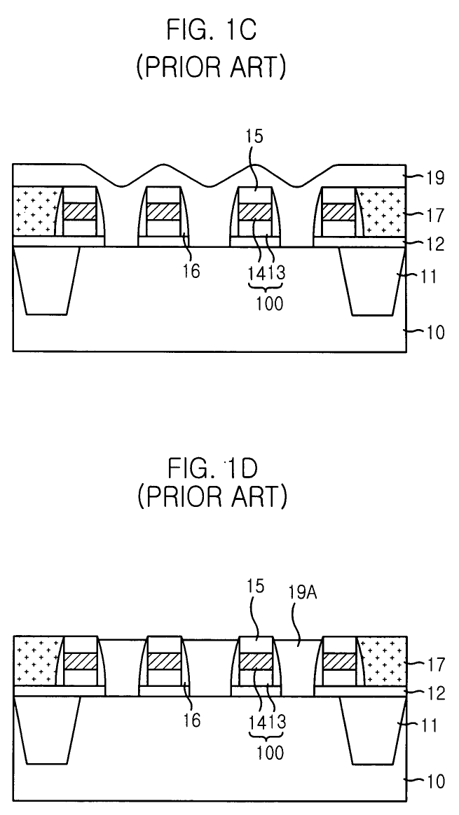

### DETAILED DESCRIPTION OF THE INVENTION

Hereinafter, a method for forming a landing plug in a semiconductor device will be described in conjunction with the provided drawings.

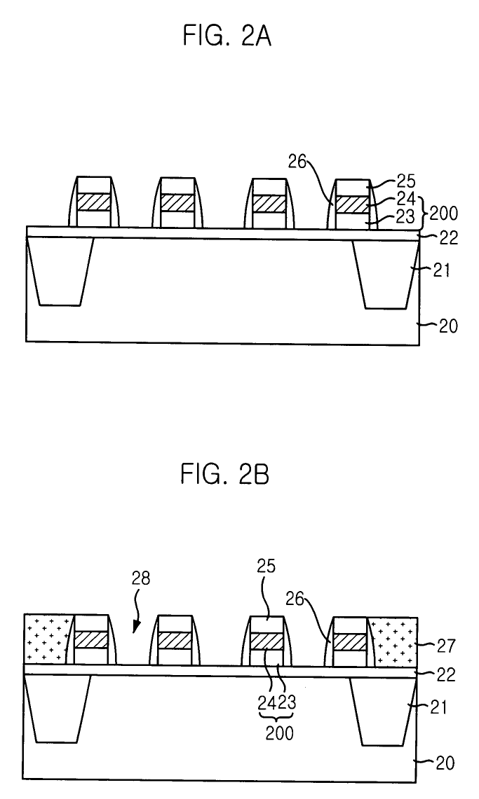

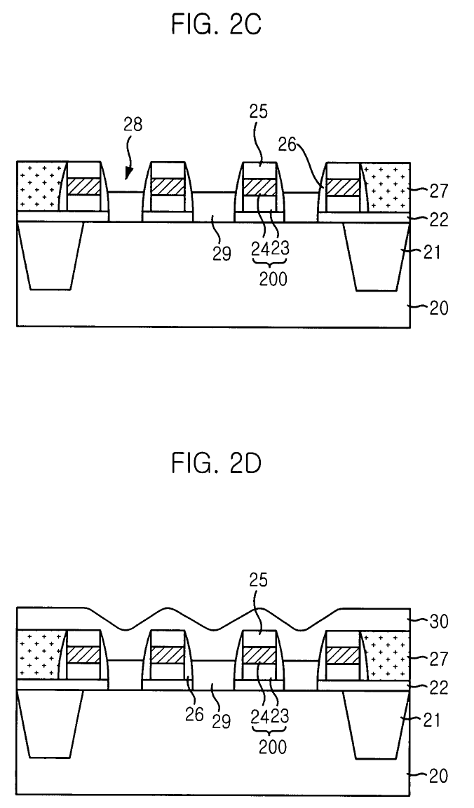

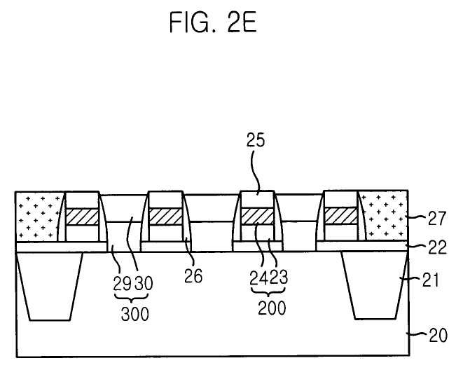

FIGS. 2A to 2E are cross-sectional views showing a method for forming a landing plug in a semiconductor device in accordance with a first preferred embodiment of the present invention.

Referring to FIG. 2A, a gate insulation layer 22 is formed on a substrate 20 providing a device isolation layer 21 with a shallow trench isolation (STI) structure. Then, a polysilicon layer 23 and a metal layer 24 are sequentially formed thereon. Herein, the substrate 20 is made of silicon and the gate insulation layer 22 is made of a silicon oxide layer employing SiO₂ or oxynitride such as Si—O—N. Also, the gate insulation layer 22 can be made of a metal oxide layer containing any metal selected from a group consisting of Hf, Zr, Al, Y, Ce, La, Th and Ta or a mixture of theses metal elements or a stacked layer containing some of the above metal elements. Moreover, the gate insulation layer 22 can be made of a silicate layer containing metal.

Next, on top of the metal layer 24, a hard mask 25 is formed, and then, the metal layer 24 and the polysilicon layer 23 are etched with use of the hard mask 25 so that a gate 200 is formed. Afterwards, an insulation layer is deposited on an entire surface of the substrate 20 and proceeded with a blanket etch process so as to form a spacer 26 at lateral sides of the hard mask 25 and the gate 200.

Referring to FIG. 2B, an inter-layer insulation layer 27 is deposited on an entire surface of the substrate 20 to fill a space between the spacers 26. Next, with use of a CMP process, the inter-layer insulation layer 27 is entirely etched to expose a surface of the hard mask 25 and the substrate 20 is planarized thereafter. Then, the inter-layer insulation layer 27 is etched in such a manner to expose a partial portion of the substrate 20 between the spacers 26, whereby a contact hole 28 is formed.

Referring to FIG. 2C, on the substrate 20 disposed inside of the contact hole 28, silicon is grown to have a predetermined thickness by employing a selective epitaxial growth (SEG) technique so that a silicon layer 29, which is a first conductive layer for a landing plug, is formed. Preferably, the silicon layer 29 has a thickness ranging from about 10 Å to about 2000 Å.

Referring to FIG. 2D, a tungsten silicide WSiₓ layer 30, which is a second conductive layer for the landing plug, is formed on the inter-layer insulating layer 27 so as to be buried into the contact hole 28 on which the silicon layer 29 is formed. Preferably, the WSiₓ layer 30 has a thickness from about 100 Å to about 2000 Å. In addition to the use of the WSiₓ layer, it is possible to use any layer selected from a group consisting of a TiSiₓ layer, a CoSiₓ layer, a NiSiₓ layer, a TaSiₓ layer, a HfSiₓ layer, a ZrSiₓ layer, a FeSiₓ layer, a YSiₓ layer and a MoSiₓ layer. At this time, the notation x indicating the number of atoms presenting in a molecule ranges from about 0.5 to about 2.5.

Referring to FIG. 2E, the WSiₓ layer 30 is entirely etched to expose surfaces of the hard mask 25 and the interlayer insulation layer 27 through a CMP process so that a landing plug 300 including the WSiₓ layer 30 and the silicon layer 29 is formed.

According to the above-preferred embodiment of the present invention, since the landing plug 300 is formed by stacking the silicon layer 29 and the WSiₓ layer 30 through the use of the SEG technique, it is possible to reduce a resistance in more extents compared to the prior art as well as to decrease a resistance-capacitance (RC) delay. These effects make further possible for the landing plug 300 to be correspondent to the demands of high-integration and high-speed in a semiconductor device. Also, the SEG technique used for forming the landing plug 300 solves the gap-fill problem arose by using the conventional method even though a contact hole depth increases and simplifies subsequently performed processes due to an elimination of the CMP process.

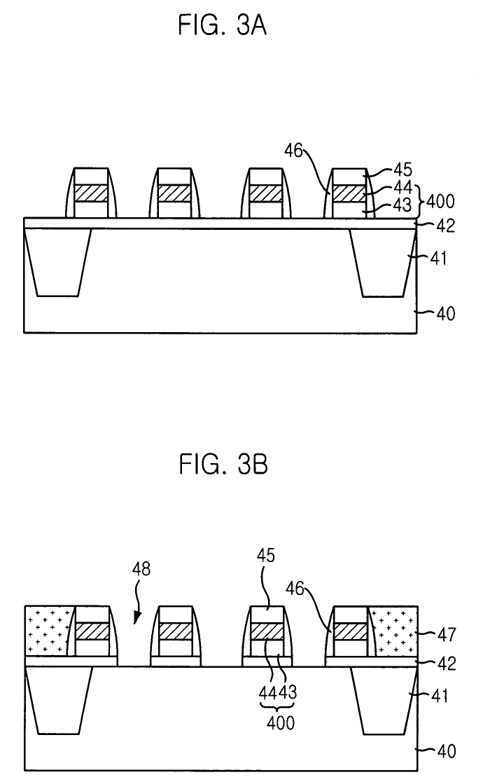

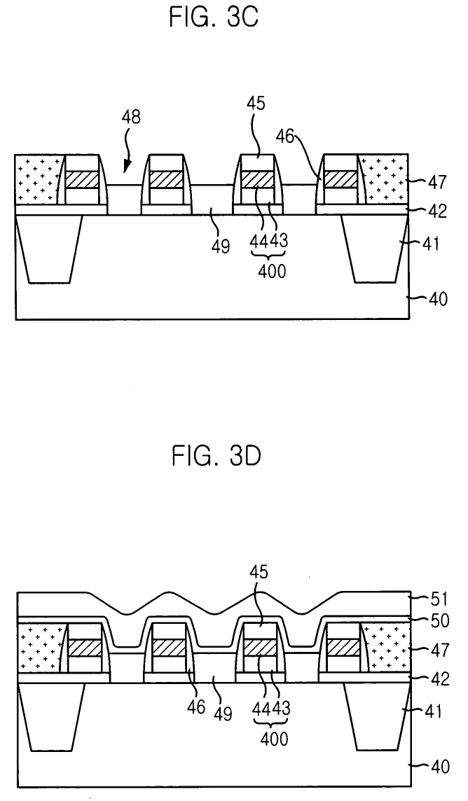

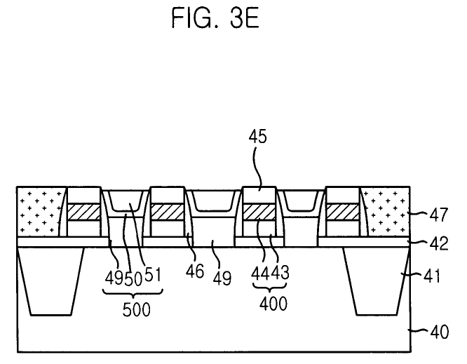

Additionally, even though the first preferred embodiment shows the case of using the WSiₓ layer 30 for the second conductive layer for the landing plug, it is possible to use alternatively a double layer of W/WNₓ formed by sequentially depositing a WNx layer and a W layer. This alternative use of the double layer will be described in the following preferred embodiment with reference to FIGS. 3A to 3E.

Referring to FIGS. 3A to 3C, a device isolation layer 41 with a STI structure is formed on a substrate 40, and then a gate insulation layer 42, a gate 400, a hard mask 45, a spacer 46, an inter-layer insulation layer 47, a contact hole 48 and a silicon layer 49 are sequentially formed on the substrate 40. Herein, the silicon layer 49 is a first conductive layer for a landing plug and is formed through a SEG technique.

Referring to FIG. 3D, a WN, layer 50, which is a second conductive layer for the landing plug, is formed on the contact hole 48 in which the silicon layer 49 is formed and a surface of the substrate 40. Afterwards, a W layer 51 is formed on the WNₓ layer 50 in such a manner of being buried into the contact hole 48 including the WNₓ layer 50. Preferably, each of the WNₓ layer 50 and the W layer 51 has a thickness ranging from about 20 Å to about 2000 Å. Also, instead of using the W layer 51, such layer including any element selected from a group consisting of Ta, Ti, Mo, Cr, Hf, Zr, Ru, Ir and Pt can be alternatively used. Instead of the WNₓ layer 50, it is possible to use metal nitride including any element selected from a group consisting of Ta, Ti, Mo, Cr, Co, Hf and Zr. At this time, the notation x indicating the number of atoms presenting in a molecule ranges from about 0.1 to about 1.0. Also, the WNₓ layer 50 can be substituted with any layer selected from a group consisting of a WsiₓN_{y} layer, a TaSiₓN_{y} layer, a TiSiₓN_{y} layer, a TiAlₓN_{y} layer, a TaAlₓN_{y} layer, a RuTiₓN_{y} layer and a RuTaₓN_{y} layer. At this time, each notation of x and y both indicating the number of atoms presenting in a molecule ranges from about 0.1 to about 4.0. Also, a RuOₓ layer or an IrOₓ layer can be used instead of the WNₓ layer 50. At this time, the notation x indicating the number of atoms presenting in a molecule ranges from about 0.1 to about 3.0.

After forming the WNₓ layer 50 and the W layer 51, an annealing process is performed for crystallization of the WNₓ layer 50 and the W layer 51 and denudation of N. Preferably, the annealing process is carried out at a temperature in a range from about 600° C. to about 1000° C. for about 10 seconds to 1 hour. At this time, the notation x indicating the number of atoms presenting in a molecule ranges from about 0.1 to about 1.0. Subsequent to the annealing process, the W layer 51 and the WNₓ layer 50 are entirely etched to expose surfaces of the hard mask 45 and the inter-layer insulating layer 47 with use of a CMP process. After these series of processes, a landing plug 500 staked of the W layer/WNₓ layer/silicon layer is formed as shown in FIG. 3E.

Meanwhile, in the second preferred embodiment, the CMP process is performed after the W layer 51 and the WNₓ layer 50 are deposited and annealed. However, it is possible to perform the CMP process prior to the annealing process. Furthermore, it is also possible to deposit solely the WNₓ layer 50 without the W layer 51. In this case, the notation x indicating the number of atoms presenting in a molecule has a value ranging from about 0.1 to about 1.0. In addition, instead of forming the WNₓ layer, a SiNe layer can be deposited to a thickness from about 10 Å to about 20 Å. At this time, the notation x indicating the number of atoms presenting in a molecule ranges from about 0.1 to about 3.0.

According to the above-described first and the second preferred embodiments, it is possible to obtain a sufficiently low resistance corresponding to demands of high-integration and high-speed in a semiconductor device by forming a landing plug in a stack layer of the silicon layer and the WSiₓ layer or the W layer and the WNₓ layer.

While the present invention has been described with respect to certain preferred embodiments, it will be apparent to those skilled in the art that various changes and modifications may be made without departing from the scope of the invention as defined in the following claims.

What is claimed is:

1. A method for forming a landing plug, comprising the steps of:
forming an inter-layer insulation layer on a substrate;
forming a contact hole by etching the inter-layer insulation layer until exposing a partial portion of the substrate;
forming a first conductive layer with a predetermined thickness inside of the contact hole, the first conductive layer being made of a silicon layer;
forming a second conductive layer on the inter-layer insulation layer in such a manner of being buried into the contact hole in which the silicon layer is formed; and
performing a blanket etch process to the second conductive layer until exposing surfaces of the inter-layer insulation layer and the hard mask so that a landing plug is formed.

2. The method as recited in claim 1, wherein the second conductive layer is made of any material selected from a group consisting of WSiₓ, TiSiₓ, CoSiₓ, CrSiₓ, NiSiₓ, TaSiₓ, HfSiₓ, ZrSiₓ, FeSiₓ, YSiₓ and MoSiₓ, and among these materials, the WSiₓ is more preferable.

3. The method as recited in claim 2, wherein the x indicating the number of atoms presenting in a molecule ranges from about 0.5 to about 2.5.

4. The method as recited in claim 2, wherein the WSiₓ layer has a thickness ranging from about 100 Å to about 2000 Å.

5. The method as recited in claim 1, wherein the second conductive layer is formed by stacking the W layer and the WNₓ layer.

6. The method as recited in claim 5, wherein each of the W layer and the WNₓ layer has a thickness in a range from about 20 Å to about 2000 Å.

7. The method as recited in claim 5, wherein the WNₓ layer is substituted with metal nitride containing any metal selected from a group consisting of Ta, Ti, Mo, Cr, Co, Hf and Zr.

8. The method as recited in claim 7, wherein the x indicating the number of atoms presenting in the molecule of WN, ranges from about 0.1 to about 1.0.

9. The method as recited in claim 5, wherein the WNₓ layer is substituted with any layer selected from a group consisting of a WSiₓN_{y} layer, a TaSiₓN_{y} layer, a TiSiₓN_{y} layer, a TiAlₓN_{y} layer, a TaAlₓN_{y} layer, a RuTiₓN_{y} layer and a RuTaₓN_{y} layer.

10. The method as recited in claim 9, wherein each of the x and y indicating the number of atoms presenting in a molecule ranges from about 0.1 to about 4.0.

11. The method as recited in claim 5, wherein the WNₓ layer is substituted with a RuOₓ layer or an IrOₓ layer.

12. The method as recited in claim 11, wherein the x indicating the number of atoms presenting in the molecule of WNₓ ranges from about 0.1 to about 3.0.

13. The method as recited in claim 5, wherein the W layer is substituted with any layer selected from a group consisting of a Ta layer, a Ti layer, a Mo layer, a Cr layer, a Co layer, a Hf layer, a Zr layer, a Ru layer, an Ir layer and a Pt layer.

14. The method as recited in claim 1, wherein the second conductive layer is proceeded with an annealing process after the step of forming the second conductive layer or the step of performing the blanket etch process.

15. The method as recited in claim 14, wherein the annealing process is carried out at a temperature ranging from about 600° C. to about 1000° C. for about 10 seconds to about 1 hour.

16. The method as recited in claim 1, wherein the silicon layer is formed through a selective epitaxial growth (SEG) technique.

17. The method as recited in claim 16, wherein the silicon layer has a thickness in a range from about 10 Å to about 2000 Å.
